(19) United States
(12) Patent Application Publication
(10) Pub. No.: US 2026/0096329 A1
(43) Pub. Date: Apr. 2, 2026

(54) ORGANIC LIGHT EMITTING DEVICE AND METHOD FOR MANUFACTURING THE SAME

(71) Applicant: TAIZHOU GUANYU TECHNOLOGY CO., LTD., ZHEJIANG PROVINCE (CN)

(72) Inventors: RENHUI RUAN, ZHEJIANG PROVINCE (CN); KUO-CHENG HSU, TAICHUNG CITY (TW)

(21) Appl. No.: 19/303,390

(22) Filed: Aug. 19, 2025

(30) Foreign Application Priority Data
Sep. 30, 2024 (CN) 202411388343.X

(51) Int. Cl. H10K 59/80; H10K 59/12; H10K 59/122

(52) U.S. Cl. CPC H10K 59/80521; H10K 59/1201; H10K 59/122

(57) ABSTRACT

A light emitting diode includes a substrate, a first bottom electrode, a first top electrode, a second top electrode, and a blocking structure. The first bottom electrode is disposed on the substrate. An organic light emitting layer structure is disposed on the first bottom electrode. The first top electrode and the second top electrode are disposed on the organic light emitting layer structure. The blocking structure is disposed on the substrate, wherein the blocking structure has a trench, and wherein the first top electrode and the second top electrode are separated from each other by the blocking structure.

### TECHNICAL FIELD

The disclosure relates to an organic light emitting device and a method for manufacturing the same. More particularly, the disclosure relates to an organic light emitting device comprising an organic light emitting diode (OLED) structure and a method for manufacturing the same.

### BACKGROUND

Currently, fine metal mask (FMM) is commonly used to coat light emitting layers of organic light emitting devices, or white light with color filters is used for the process. The pixel fineness or resolution produced by the above-mentioned processes is unsatisfactory.

### SUMMARY

In the disclosure, a light emitting diode comprises a substrate, a first bottom electrode, a first top electrode, a second top electrode, and a blocking structure. The first bottom electrode is disposed on the substrate. An organic light emitting layer structure is disposed on the first bottom electrode. The first top electrode and the second top electrode are disposed on the organic light emitting layer structure. The blocking structure is disposed on the substrate, wherein the blocking structure has a trench, and wherein the first top electrode and the second top electrode are separated from each other by the blocking structure.

In the disclosure, a method for manufacturing an organic light emitting device comprises: providing a substrate; disposing a first bottom electrode on the substrate; forming a blocking structure on the substrate; forming a trench in the blocking structure; forming an organic light emitting layer structure on the first bottom electrode and the blocking structure; and forming a top electrode material layer over the blocking structure and the substrate, such that the top electrode material layer is cut off by the blocking structure to form a first top electrode and a second top electrode that are separated from each other.

In some embodiments, the blocking structure comprises a plurality of blocking strips separated from each other by the trench.

In some embodiments, the organic light emitting layer structure comprises a first organic light emitting layer and a second organic light emitting layer. The first organic light emitting layer is disposed between the first bottom electrode and the first top electrode. The second organic light emitting layer is disposed between the first bottom electrode and the second top electrode, wherein the first organic light emitting layer and the second organic light emitting layer are separated from each other by the trench.

In some embodiments, the first top electrode and the second top electrode have an extension direction substantially parallel to an extension direction of the trench.

In some embodiments, the organic light emitting layer structure comprises a first organic light emitting layer, a second organic light emitting layer, and a plurality of first organic material layers. The first top electrode and the second top electrode are disposed on the first organic light emitting layer and the second organic light emitting layer, respectively. The first organic material layers are disposed on the blocking strips.

In some embodiments, the organic light emitting layer structure further comprises a second organic material layer disposed in the trench.

In some embodiments, the trench has an extension direction substantially perpendicular to an extension direction of the first bottom electrode.

In some embodiments, the organic light emitting device further comprises a pixel defined layer disposed on the substrate between the first top electrode and the second top electrode, wherein the blocking structure is disposed on the pixel defined layer.

In some embodiments, the organic light emitting device further comprises a pixel defined layer disposed on the substrate between the first top electrode and the second top electrode, wherein the trench of the blocking structure is recessed toward an inside of the pixel defined layer.

In some embodiments, the organic light emitting device further comprises a pixel defined layer disposed on the substrate between the first top electrode and the second top electrode, wherein the pixel defined layer partially extends onto the blocking structure.

In some embodiments, the blocking structure has a cross sectional width tapering toward the substrate.

In some embodiments, the trench exposes a top surface of the first bottom electrode.

In some embodiments, the organic light emitting device comprises a plurality of the trench, wherein at least two of the trenches have different widths.

In some embodiments, the method further comprises: forming a pixel defined layer on the substrate and partially covering the first bottom electrode; and forming the blocking structure on the pixel defined layer, wherein the top electrode material layer is cut off by a height difference between the blocking structure and the pixel defined layer.

In some embodiments, the method further comprises: forming the trench in the blocking structure and further extending the trench into the pixel defined layer by an etching step.

In some embodiments, the method further comprises: forming a pixel defined layer on the substrate and partially covering the first bottom electrode and the blocking structure, wherein the top electrode material layer is cut off by the trench.

In some embodiments, forming the pixel defined layer is carried out after forming the trench.

### BRIEF DESCRIPTION OF THE DRAWINGS

FIG. 1 is a top view exemplarily showing an intermediate product of an organic light emitting device.

FIG. 2A is a cross sectional view exemplarily showing an organic light emitting device.

FIG. 2B is a cross sectional view exemplarily showing an organic light emitting device.

FIG. 2C is a cross sectional view exemplarily showing an organic light emitting device.

FIG. 2D is a cross sectional view exemplarily showing an organic light emitting device.

FIG. 2E is a top view exemplarily showing a region of FIG. 1.

FIG. 2F is a cross sectional view exemplarily showing an organic light emitting device.

FIG. 3A is a cross sectional view exemplarily showing an organic light emitting device.

FIG. 3B is a cross sectional view exemplarily showing an organic light emitting device.

FIG. 3C is a cross sectional view exemplarily showing an organic light emitting device.

FIGS. 4A-4F show a method for manufacturing an organic light emitting device according to some embodiments.

FIGS. 5A-5F show a method for manufacturing an organic light emitting device according to some embodiments.

### DETAILED DESCRIPTION

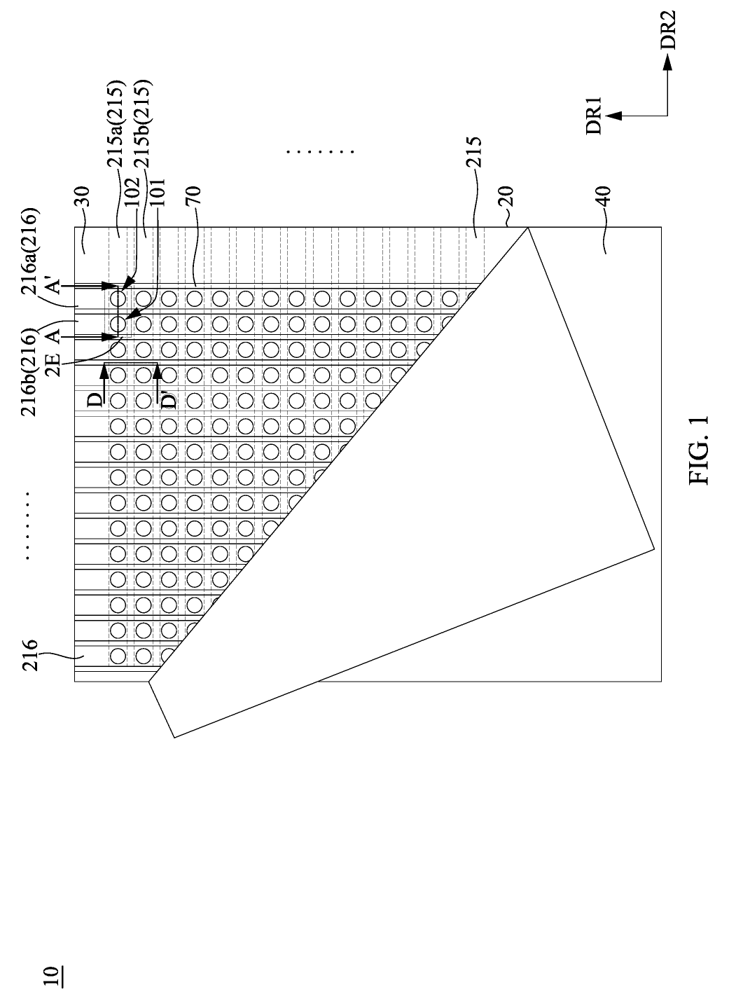

FIG. 1 is a top view exemplarily showing an intermediate product of an organic light emitting device 10. The organic light emitting device 10 may comprise a light emitting layer 20 and a covering layer 40 disposed on the light emitting layer 20. For the light emitting layer 20, a spacer structure 30 may be designed to provide a recess array for accommodating a light emitting pixel array. In some embodiments, the spacer structure 30 is used as a pixel defined layer (PDL). In some embodiments, the spacer structure 30 may comprise a protrusion 310. In some embodiments, the protrusion 310 defines a pixel region. In some embodiments, the spacer structure 30 may comprise a light sensitive material.

As shown in FIG. 1, the organic light emitting device 10 may further comprise an electrode 215 (also referred to as a bottom electrode) and an electrode 216 (also referred to as a top electrode). In some embodiments, the electrode 215 is an anode, and the electrode 216 is a cathode. In some embodiments, the organic light emitting device 10 may comprise a plurality of electrodes 215 and a plurality of electrodes 216, such as electrodes 215a and 215b and electrodes 216a and 216b. In some embodiments, the electrodes 215 have an extension direction DR2 substantially perpendicular to an extension direction DR1 of the electrodes 216. The organic light emitting device 10 may further comprise a blocking structure 70. In some embodiments, the extension direction DR1 of the electrodes 216 is substantially parallel to an extension direction DR1 of the blocking structure 70. In some embodiments, the extension direction DR2 of the electrodes 215 is substantially perpendicular to the extension direction DR1 of the blocking structure 70.

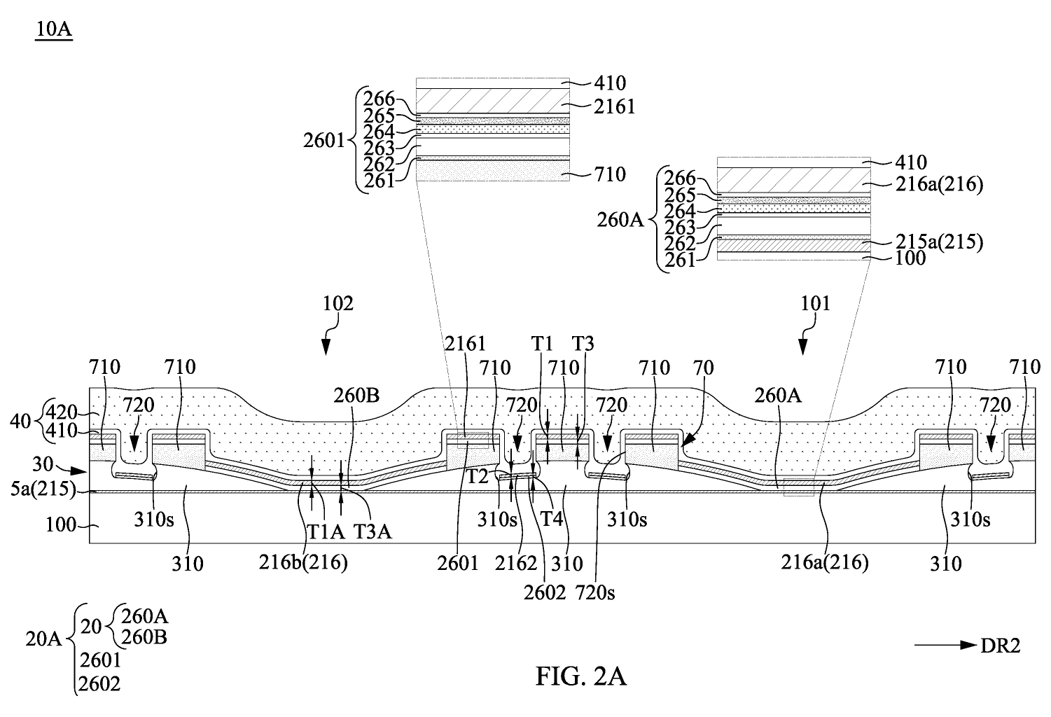

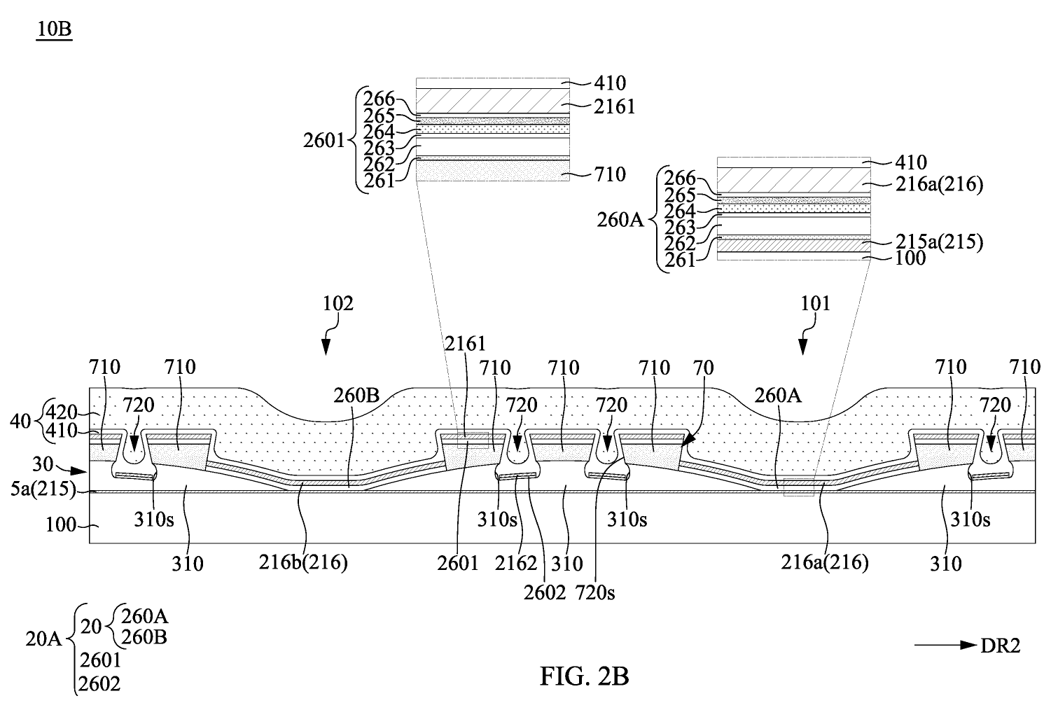

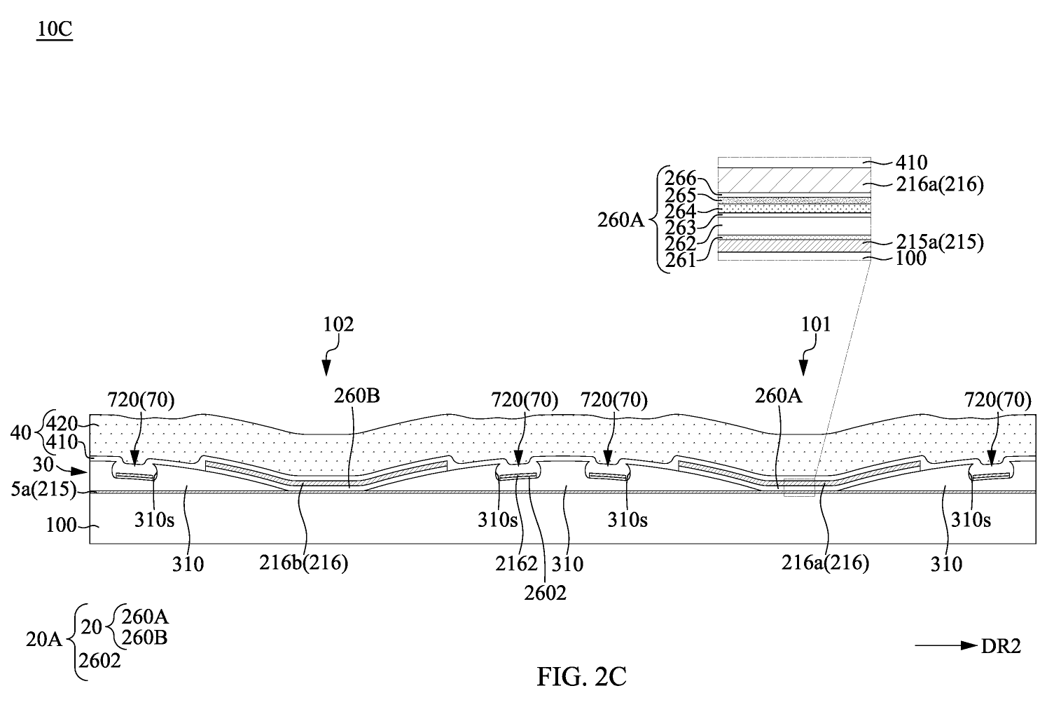

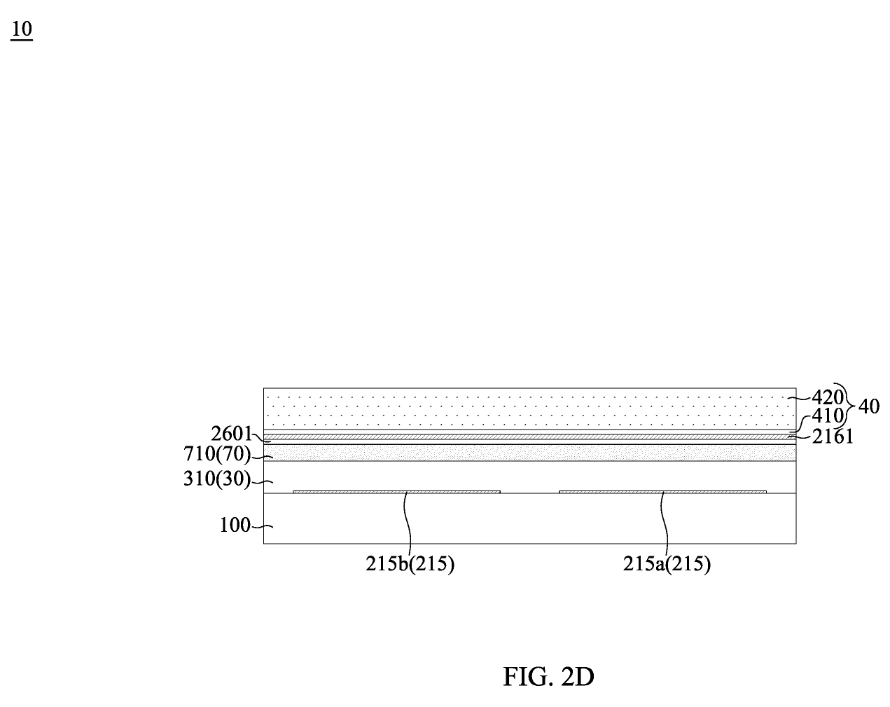

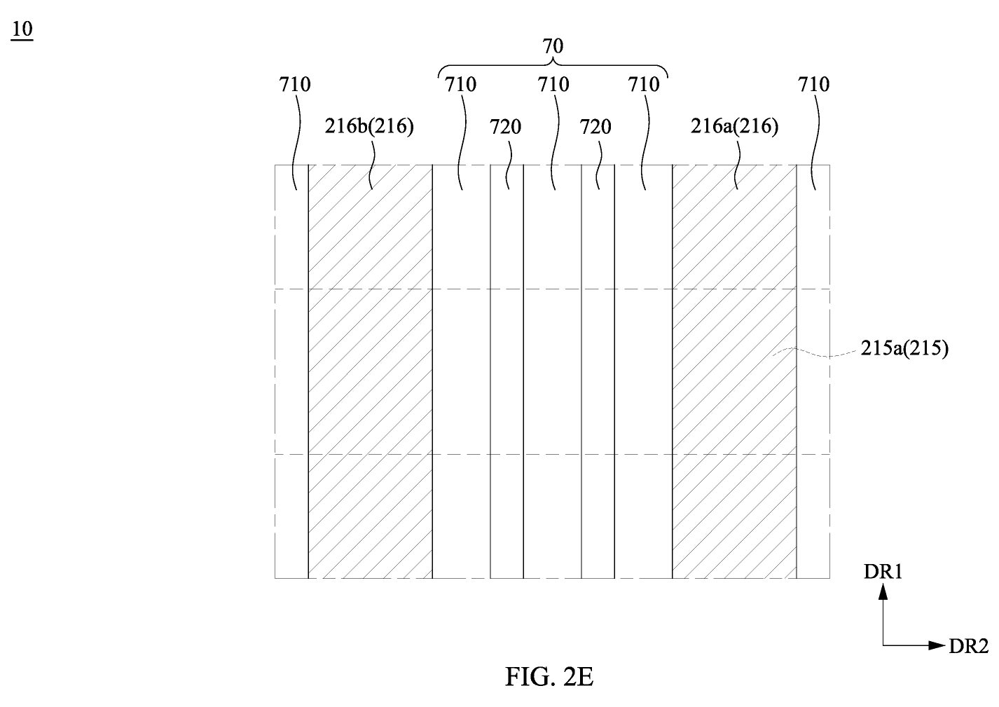

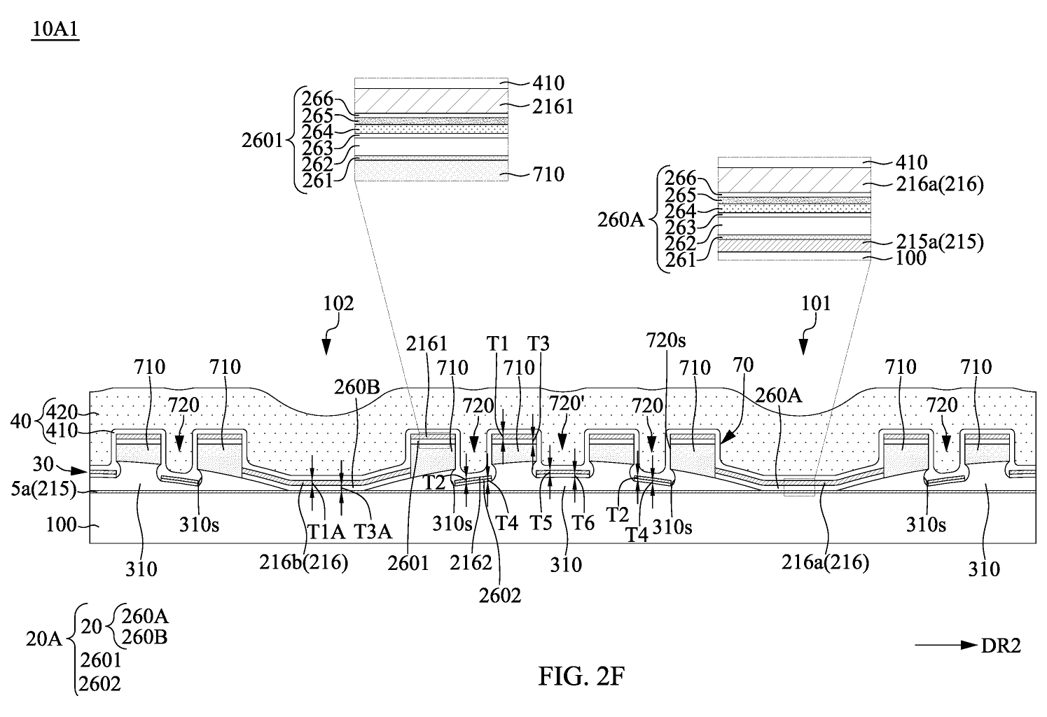

FIG. 2A is a cross sectional view exemplarily showing an organic light emitting device 10A. In some embodiments, FIG. 2A is a cross sectional view exemplarily taken along line A-A’ in FIG. 1. In some embodiments, FIG. 2A is a cross sectional view exemplarily taken along line A-A’ in FIG. 1 and illustrating only a light emitting region. The spacer structure 30 has a plurality of protrusions 310 to define a light emitting pixel pattern. A recess is located between two adjacent protrusions 310 and provides space for accommodating a light emitting pixel. One skilled in the art should understand that the protrusions 310 are shown to be disconnected in the cross sectional view of FIG. 2A, but they are shown to be connectable to each other through other portions of the spacer structure 30 in the top view of FIG. 1.

As shown in FIG. 2A, in some embodiments, the organic light emitting device 10 is, for example, a light emitting device comprising an organic light emitting diode (OLED) structure. In some embodiments, the organic light emitting device 10 comprises a plurality of organic light emitting units (also referred to as light emitting pixels), for example, comprises at least an organic light emitting unit 101 (also referred to as a first organic light emitting unit) and an organic light emitting unit 102 (also referred to as a second organic light emitting unit). In some embodiments, the organic light emitting units 101 and 102 are located between the protrusion 310 and above a substrate 100. The organic light emitting units 101 and 102 may emit light of the same wavelength or light of different wavelengths.

In some embodiments, the organic light emitting device 10 comprises the substrate 100, the electrode 215a (also referred to as a first bottom electrode), the electrode 216a (also referred to as a first top electrode), the electrode 216b (also referred to as a second top electrode), electrode material layers 2161 and 2162, an organic light emitting layer structure 20A, the spacer structure 30 (also referred to as a pixel definition layer), and the covering layer 40.

In some embodiments, the substrate 100 may comprise a transistor array arranged corresponding to the light emitting pixels in the light emitting layer 20. The substrate 100 may comprise a plurality of capacitors. In some embodiments, more than one transistor is arranged together with a capacitor and a light-emitting pixel to form a circuit. In some embodiments, the substrate 100 may comprise glass.

In some embodiments, the organic light emitting layer structure 20A is disposed on the electrodes 215. In some embodiments, the organic light emitting layer structure 20A comprises the light emitting layer 20 and a plurality of organic material layers 2601 and 2602. In some embodiments, the light emitting layer 20 comprises an organic light emitting layer 260A (also referred to as a first organic light emitting layer) and an organic light emitting layer 260B (also referred to as a second organic light emitting layer).

In some embodiments, the electrode 215a is disposed on the substrate 100. In some embodiments, the electrode 215a is an anode. In some embodiments, the electrode 215a comprises a metal material, such as Ag, Al, Mg, Au, AlCu alloy, AgMo alloy, or the like. In some embodiments, the electrode 215a comprises indium tin oxide (ITO), indium zinc oxide (ITO), or other suitable materials. In some embodiments, the organic light emitting layer 260A and the organic light emitting layer 260B are disposed on the electrode 215a.

In some embodiments, the electrode 216a and the electrode 216b are disposed on the organic light emitting layer structure 20A. In some embodiments, the electrode 216a is disposed on the organic light emitting layer 260A, and the electrode 216b is disposed on the organic light emitting layer 260B. In some embodiments, the electrode 216a contacts the organic light emitting layer 260A, and the electrode 216b contacts the organic light emitting layer 260B. In some embodiments, the electrodes 216a and 216b may be further disposed on the spacer structure 30 (or the pixel defined layer). In some embodiments, the electrodes 216a and 216b comprise a metal material, such as Ag, Al, Mg, Au, AlCu alloy, AgMo alloy, or the like. In some embodiments, the electrodes 216a and 216b comprise indium tin oxide (ITO), indium zinc oxide (ITO), or other suitable materials.

In some embodiments, the blocking structure 70 is disposed on the substrate 10. In some embodiments, the blocking structure 70 has one or more trenches 720. In some embodiments, the blocking structure comprises a plurality of blocking strips 710 separated from each other by the trench(es) 720. In some embodiments, the electrode 216a and the electrode 216b are separated from each other by the blocking structure 70. In some embodiments, the electrode 216a and the electrode 216b are electrically isolated or electrically insulated from each other by the blocking structure 70. In some embodiments, the electrode 216a and the electrode 216b are electrically isolated or electrically insulated from each other by the blocking strips 710. In some embodiments, the electrode 216a and the electrode 216b are electrically isolated or electrically insulated from each other by the trench(es) 720. In some embodiments, the blocking structure 70 has a thickness equal to or greater than 1 μm, such as 1 μm to 4 μm, or 2 μm to 3 μm. In some embodiments, the thickness of the blocking structure 70 is greater than a thickness of the electrodes 216. In some embodiments, the thickness of the blocking structure 70 is more than 10 times the thickness of the electrodes 216, such as 20 to 30 times. In some embodiments, the blocking structure 70 may comprise a light sensitive material, and the trench 720 may have a width equal to or greater than 1 μm, such as 1 μm to 4 μm, or 2 μm to 3 μm. In some embodiments, the blocking structure 70 may comprise an inorganic oxide such as silicon oxide, silicon nitride, or silicon oxynitride, and the trench 720 may have a width equal to or greater than 0.5 μm, such as 0.5 μm to 0.7 μm, or 0.5 μm to 0.6 μm.

In some embodiments, the organic light emitting layer 260A is disposed between the electrode 215a and the electrode 216a, and the organic light emitting layer 260B is disposed between the electrode 215a and the electrode 216b. In some embodiments, the organic light emitting layer 260A and the organic light emitting layer 260B are separated from each other by the blocking structure 70. In some embodiments, the organic light emitting layer 260A and the organic light emitting layer 260B are separated from each other by the blocking strips 710. In some embodiments, the organic light emitting layer 260A and the organic light emitting layer 260B are separated from each other by the trench(es) 720. In some embodiments, the thickness of the blocking structure 70 is greater than a thickness of the organic light emitting layers 260A and 260B. In some embodiments, the thickness of the blocking structure 70 is more than 10 times the thickness of the organic light emitting layers 260A and 260B, such as 10 to 20 times. In some embodiments, the organic light emitting layers 260A and 260B emit light of the same color or light of different colors. In some embodiments, an emission wavelength of the organic light emitting layer 260A is the same as an emission wavelength of the organic light emitting layer 260B. In some embodiments, an emission wavelength of the organic light emitting layer 260A is greater than an emission wavelength of the organic light emitting layer 260B.

In some embodiments, the organic material layer 2601 (also referred to as a first organic material layer) is disposed on the blocking strips 710. In some embodiments, the organic material layer 2602 (also referred to as a second organic material layer) is disposed in the trench 720. In some embodiments, the organic material layers 2601 and 2602 comprises an organic material. In some embodiments, a thickness T3 of the organic material layer 2601 is greater than a thickness T4 of the organic material layer 2602. In some embodiments, the thickness T3 of the organic material layer 2601 is substantially equal to the thickness T3A of the organic light emitting layers 260A and 260B. In some embodiments, the electrode material layer 2161 is disposed on the blocking strips 710. In some embodiments, the electrode material layer 2162 is disposed in the trench 720. In some embodiments, a material of the electrode material layers 2161 and 2162 is the same as a material of the electrodes 216. In some embodiments, a thickness T1 of the electrode material layer 2161 is greater than a thickness T2 of the electrode material layer 2162. In some embodiments, the thickness T1 of the electrode material layer 2161 is substantially equal to the thickness T1A of the electrodes 216.

In some embodiments, the organic light emitting layers 260A and 260B comprise an organic material, which may be disposed in any material layer of the organic light emitting layers 260A and 260B based on different implementations. In some embodiments, the organic material has an absorptivity equal to or greater than 50% for a specific wavelength. In some embodiments, the organic material has an absorptivity equal to or greater than 60% for a specific wavelength. In some embodiments, the organic material has an absorptivity equal to or greater than 70% for a specific wavelength. In some embodiments, the organic material has an absorptivity equal to or greater than 80% for a specific wavelength. In some embodiments, the organic material has an absorptivity equal to or greater than 90% for a specific wavelength. In some embodiments, the organic material has an absorptivity equal to or greater than 95% for a specific wavelength. In some embodiments, the specific wavelength is not greater than 400 nm. In some embodiments, the specific wavelength is not greater than 350 nm. In some embodiments, the specific wavelength is not greater than 300 nm. In some embodiments, the specific wavelength is not greater than 250 nm. In some embodiments, the specific wavelength is not greater than 200 nm. In some embodiments, the specific wavelength is not greater than 150 nm. In some embodiments, the specific wavelength is not greater than 100 nm.

As shown in FIG. 2A, in some embodiments, each of the organic light emitting layer 260A, the organic light emitting layer 260B, the organic material layer 2601, and the organic material layer 2602 comprise a plurality of material layers, such as a hole injection layer (HIL) 261, a hole transport layer (HTL) 262, an electron blocking layer (EBL) 263, an organic emission layer (EM) 264, an electron transport layer (ETL) 265, and an electron injection layer (EIL) 266. In some embodiments, the organic light emitting unit 101 comprises the electrode 215a (also referred to as the first bottom electrode), the organic light emitting layer 260A, and the electrode 216a (also referred to as the first top electrode). In some embodiments, the organic light emitting unit 102 comprises the electrode 215a (also referred to as the first bottom electrode), the organic light emitting layer 260B, and the electrode 216b (also referred to as the second top electrode).

In some embodiments, the spacer structure 30 is disposed on the substrate 100 and partially covering the electrode 215a. In some embodiments, the spacer structure 30 is disposed between the organic light emitting layers 260A and 260B. In some embodiments, the spacer structure 30 is disposed between the electrode 216a and the electrode 216b. In some embodiments, a pattern of the spacer structure 30 is designed based on a pixel arrangement. In some embodiments, the spacer structure 30 is used as the pixel defined layer (PDL). In some embodiments, the spacer structure 30 may comprise the protrusions 310. In some embodiments, the protrusions 310 define the pixel region. In some embodiments, the electrode 215a is partially cover by the protrusions 310.

In some embodiments, the blocking structure 70 is disposed on the spacer structure 30 (or the pixel defined layer). In some embodiments, the thickness of the blocking structure 70 is 0.2 to 2 times or 0.3 to 1.2 times a thickness of the spacer structure 30 (or the pixel defined layer). In some embodiments, the thickness of the spacer structure 30 is equal to or greater than 0.5 μm, such as 0.5 μm to 2 μm, or 0.6 μm to 1 μm. In some embodiments, the trench 720 of the blocking structure 70 is recessed toward an inside of the spacer structure 30 (or the pixel defined layer). In some embodiments, the trench 720 extends downward to the inside of a protrusion 310. In some embodiments, the trench 720 is defined by sidewalls 720s of the blocking strips 710 and inner walls 310s of the protrusion 310. In some embodiments, a width of the trench 720 within the protrusion 310 is greater than a width of the trench 720 within the blocking strips 710.

In some embodiments, the spacer structure 30 (or the pixel defined layer) comprise an organic insulating material. In some embodiments, the spacer structure 30 comprise a light sensitive material. In some embodiments, the spacer structure 30 may further comprise quantum dots having excellent light absorption efficiency. In some embodiments, the spacer structure 30 may further comprise a carbon black material, such as carbon black nanoparticles, conductive fibers containing carbon black, or the like. In some embodiments, the spacer structure 30 may further comprise a black body material having an absorptivity of 90%, 95%, 99%, 99.5%, or more than 99.9% for visible light.

In some embodiments, the spacer structure 30 has an absorptivity equal to or greater than 50% for a specific wavelength. In some embodiments, the spacer structure 30 has an absorptivity equal to or greater than 60% for a specific wavelength. In some embodiments, the spacer structure 30 has an absorptivity equal to or greater than 70% for a specific wavelength. In some embodiments, the spacer structure 30 has an absorptivity equal to or greater than 80% for a specific wavelength. In some embodiments, the spacer structure 30 has an absorptivity equal to or greater than 90% for a specific wavelength. In some embodiments, the spacer structure 30 has an absorptivity equal to or greater than 95% for a specific wavelength. In some embodiments, the specific wavelength is not greater than 400 nm. In some embodiments, the specific wavelength is not greater than 350 nm. In some embodiments, the specific wavelength is not greater than 300 nm. In some embodiments, the specific wavelength is not greater than 250 nm. In some embodiments, the specific wavelength is not greater than 200 nm. In some embodiments, the specific wavelength is not greater than 150 nm. In some embodiments, the specific wavelength is not greater than 100 nm.

In some embodiments, the capping layer 40 comprises a capping layer 410 and an encapsulation layer 420. In some embodiments, the capping layer 410 is disposed on the electrodes 216a and 216b and the blocking structure 70, and is substantially conformal to non-planar top surfaces of the electrodes 216a and 216b and the blocking structure 70. The capping layer 410 may comprise a dielectric material or an inorganic insulating material, such as silicon oxide. In some embodiments, the capping layer 410 may comprise a hole transport layer material for extracting light lost inside the organic light emitting device to increase the light emitting efficiency. The capping layer 410 may also be referred to as a light extraction layer.

In some embodiments, the encapsulation layer 420 is disposed on the capping layer 410, and is substantially conformal to a non-planar top surface of the capping layer 410. The encapsulation layer 420 may comprise an oxide, such as silicon oxide. In some embodiments, the encapsulation layer 420 is substantially conformal to the non-planar top surface of the capping layer 410, and comprises a plurality of recesses corresponding to the organic light emitting layers 260A and 260B. The encapsulation layer 420 may comprise an organic polymer material, such as an epoxy-based material.

According to some embodiments of the disclosure, the plurality of electrodes 216 are separated from each other by the blocking structure 70, and cross perpendicularly with the plurality of electrodes 215 in the plurality of light emitting units (or light emitting pixels). The height difference provided by the blocking structure 70 allows the plurality of electrodes 216 to be physically separated from each other, without the need to pattern the electrode material using photolithography and etching processes to form the plurality of electrodes 216 that are separated from each other. Accordingly, the process steps of the electrodes 216 can be simplified, and the plurality of light emitting units (or light emitting pixels) can be controlled to light up individually such that the organic light emitting device 10 can display various predetermined light emitting patterns. For example, when the organic light emitting device 10 is applied in a sighting device, it may be designed based on ballistics to present a displayed image of a plurality of points.

Also, according to some embodiments of the disclosure, the height difference provided by the blocking structure 70 allows the plurality of electrodes 216 to be physically separated from each other, thereby reducing or preventing damage to the organic light emitting layers 260A and 260B under the electrodes 216 caused by etching processes, and thus the reliability and process yield of the organic light emitting device 10 can be improved.

Furthermore, according to some embodiments of the disclosure, the plurality of electrodes 216 are separated from each other by the trench 720 for electrical isolation or electrical insulation. An additional step difference is provided by the trench 720, and thus even if the height difference provided by the blocking structure 70 is not enough to break the whole electrode material layer, the step difference provided by trench 720 can effectively further break the electrode material layer, thereby more thoroughly physically separating the plurality of electrodes 216. Therefore, the issue of short circuits between adjacent light emitting units (or light emitting pixels) leading to single point lighting failure can be effectively prevented.

In addition, according to some embodiments of the disclosure, the plurality of electrodes 216 are separated from each other by the plurality of blocking strips 710 for electrical isolation or electrical insulation. Through the design of the plurality of blocking strips 710, a width and a height (or a step difference) of the trench 720 are defined, and thus the electrode material layer can be effectively broken, thereby more thoroughly physically separating the plurality of electrodes 216.

Furthermore, according to some embodiments of the disclosure, the organic light emitting layer 260A and the organic light emitting layer 260B are separated from each other by the blocking structure 70. Accordingly, it is not necessary to use photolithography and etching processes to pattern an organic light emitting material to form the plurality of organic light emitting layers that are separated from each other. Therefore, the process steps of the organic light emitting layers can be simplified.

FIG. 2B is a cross sectional view exemplarily showing an organic light emitting device 10B. In some embodiments, FIG. 2B is a cross sectional view exemplarily showing the organic light emitting device of FIG. 1. In some embodiments, FIG. 2B is a cross sectional view exemplarily taken along line A-A’ in FIG. 1. In some embodiments, FIG. 2B is a cross sectional view exemplarily taken along line A-A’ in FIG. 1 and illustrating only a light emitting region. FIG. 2B has a structure similar to the structure of FIG. 2A, with a difference described as follows.

In some embodiments, the trench 720 of the blocking structure 70 is recessed toward an inside of the spacer structure 30 (or the pixel defined layer). In some embodiments, the trench 720 extends downward to the inside of a protrusion 310. In some embodiments, the trench 720 is defined by sidewalls 720s of the blocking strips 710 and inner walls 310s of the protrusion 310. In some embodiments, a width of the trench 720 within the protrusion 310 is greater than a width of the trench 720 within the blocking strips 710. In some embodiments, the blocking structure 70 (or a blocking strip 710) has a cross sectional width tapering toward the spacer structure 30. In some embodiments, the blocking strips 710 have inclined sidewalls 720s.

According to some embodiments of the disclosure, the blocking strips 710 have the inclined sidewalls 720s, making it difficult for the whole electrode material layer to be formed on the inclined sidewalls 720s, and thus the blocking strips 710 can break the plurality of electrodes 216 more effectively.

FIG. 2C is a cross sectional view exemplarily showing an organic light emitting device 10C. In some embodiments, FIG. 2C is a cross sectional view exemplarily showing the organic light emitting device of FIG. 1. In some embodiments, FIG. 2C is a cross sectional view exemplarily taken along line A-A’ in FIG. 1. In some embodiments, FIG. 2C is a cross sectional view exemplarily taken along line A-A’ in FIG. 1 and illustrating only a light emitting region. FIG. 2C has a structure similar to the structure of FIG. 2A, with a difference described as follows.

In some embodiments, the trench 720 of the blocking structure 70 is recessed toward an inside of the spacer structure 30 (or the pixel defined layer). In some embodiments, the trench 720 extends downward to the inside of a protrusion 310. In some embodiments, the trench 720 is defined by inner walls 310s of the protrusion 310. In some embodiments, the electrode 216a and the electrode 216b are separated from each other by the trench(es) 720. In some embodiments, the blocking structure 70 of the organic light emitting device 10C has no blocking strips 710. In some embodiments, the blocking strips 710 and the electrode material layer 2161 thereon are removed during the processes, so that on a portion of the spacer structure 30, there is no blocking structure 70.

According to some embodiments of the disclosure, the blocking structure 70 of the organic light emitting device 10C has no blocking strips 710, and the plurality of electrodes 216 are separated from each other by the trench(es) 720. Accordingly, there are no blocking strips 710 on the spacer structure 30, and the capping layer 410 and the encapsulation layer 420 can be formed on a relatively planar surface. Therefore, stress concentration points in the capping layer 410 become fewer, thereby the cap layer 410 is less likely to be damaged, and the overall size of the organic light emitting device 10C can be further reduced.

FIG. 2D is a cross sectional view exemplarily showing the organic light emitting device 10. In some embodiments, FIG. 2D is a cross sectional view exemplarily taken along line D-D’ in FIG. 1. In some embodiments, FIG. 2D is a cross sectional view exemplarily taken along line D-D’ in FIG. 1 and illustrating only a light emitting region.

In some embodiments, the electrode 215a and the electrode 215b are separated from each other by the spacer structure 30 (or the pixel defined layer). In some embodiments, the electrodes 215a and 215b and the blocking structure 70 are separated from each other by the spacer structure 30 (or the pixel defined layer).

FIG. 2E is a top view exemplarily showing the organic light emitting device 10. In some embodiments, FIG. 2E is a top view exemplarily showing a region 2E of FIG. 1. In some embodiments, FIG. 2E is a top view exemplarily showing a region 2E of FIG. 1 and illustrating only a light emitting region.

In some embodiments, the extension direction DR2 of the electrode 215a (or the electrodes 215) is substantially perpendicular to the extension direction DR1 of the electrodes 216a and 216b (or the electrodes 216).

In some embodiments, the extension direction DR2 of the electrodes 215 is substantially perpendicular to an extension direction DR1 of the blocking strips 710. In some embodiments, the extension direction DR2 of the electrodes 215 is substantially perpendicular to an extension direction DR1 of the trench 720.

In some embodiments, the extension direction DR1 of the electrodes 216a and 216b (or the electrodes 216) is substantially parallel to the extension direction DR1 of the blocking strips 710. In some embodiments, the extension direction DR1 of the electrodes 216a and 216b (or the electrodes 216) is substantially parallel to the extension direction DR1 of the trench 720.

FIG. 2F is a cross sectional view exemplarily showing an organic light emitting device 10A1. In some embodiments, FIG. 2F is a cross sectional view exemplarily showing the organic light emitting device 10 of FIG. 1. In some embodiments, FIG. 2F is a cross sectional view exemplarily taken along line A-A’ in FIG. 1. In some embodiments, FIG. 2F is a cross sectional view exemplarily taken along line A-A’ in FIG. 1 and illustrating only a light emitting region. FIG. 2F has a structure similar to the structure of FIG. 2A, with a difference described as follows.

In some embodiments, the trench 720 and a trench 720' of the blocking structure 70 have different widths. In some embodiments, the width of the trench 720' is greater than the width of the trench 720. In some embodiments, an opening of the trench 720' is larger than an opening of the trench 720. In some embodiments, the trench 720' is disposed between two trenches 720.

In some embodiments, the thickness T1 of the electrode material layer 2161 on the blocking strips 710 is greater than the thickness T2 of the electrode material layer 2162 remaining in the trench 720 and a thickness T5 of the electrode material layer 2162 remaining in the trench 720’. In some embodiments, the thickness T3 of the organic material layer 2601 on the blocking strips 710 is greater than the thickness T4 of the organic material layer 2602 remaining in the trench 720 and a thickness T6 of the organic material layer 2602 remaining in the trench 720’. In some embodiments, since the opening of trench 720' is larger than the opening of trench 720, more evaporation material enters the trench 720' than the trench 720, and thus the thickness T2 of the electrode material layer 2162 remaining in the trench 720 is smaller than the thickness T5 of the electrode material layer 2162 remaining in the trench 720'. In some embodiments, since the opening of trench 720' is larger than the opening of trench 720, more evaporation material enters the trench 720' than the trench 720, and thus the thickness T4 of the organic material layer 2602 remaining in the trench 720 is smaller than the thickness T6 of the organic material layer 2602 remaining in the trench 720'.

According to some embodiments of the disclosure, through the design that makes the trench 720' having the larger width or opening, even if the whole electrode material layer and the whole organic material layer are not completely broken within the trench 720, better blocking can be achieved by the trench 720', and thus the plurality of electrodes 216 can be broken apart more effectively.

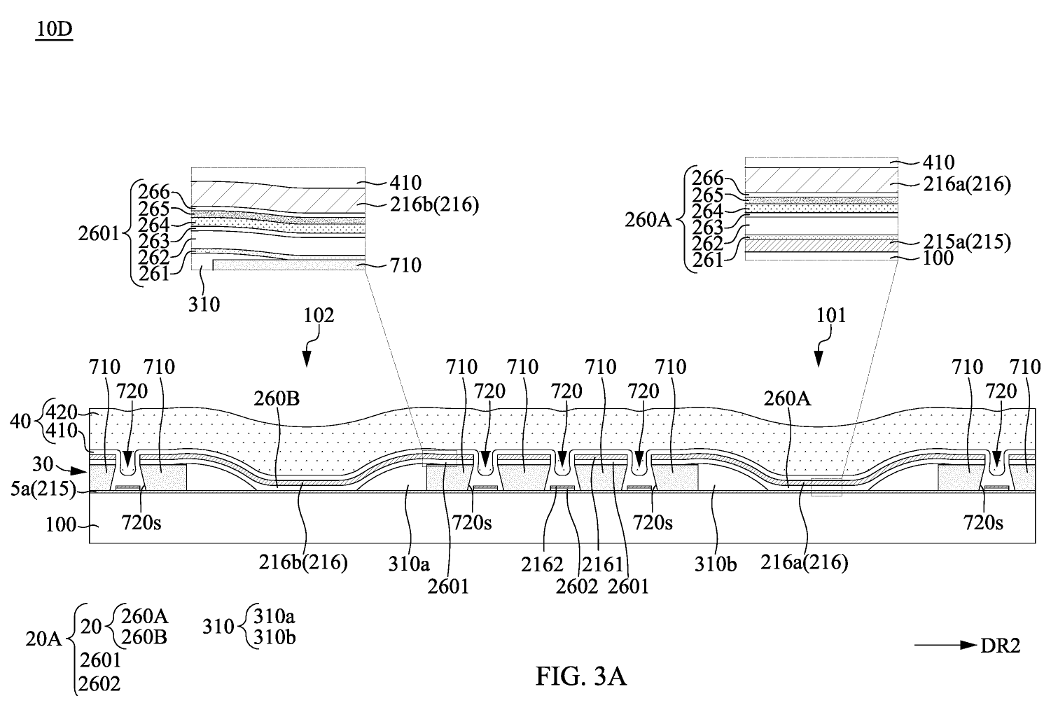

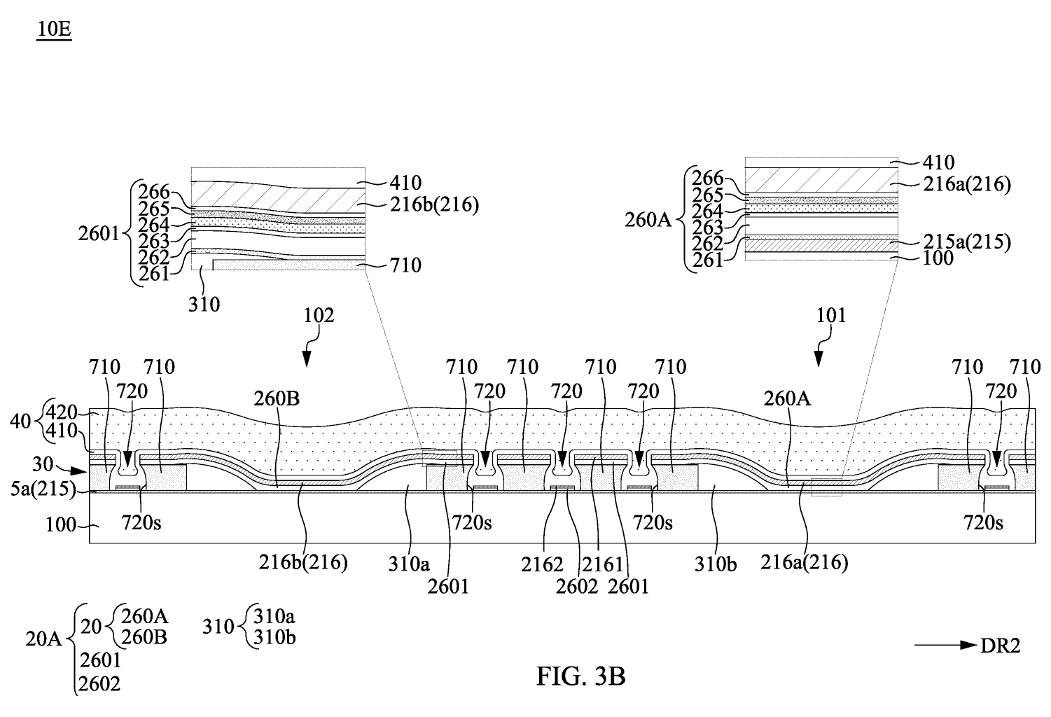

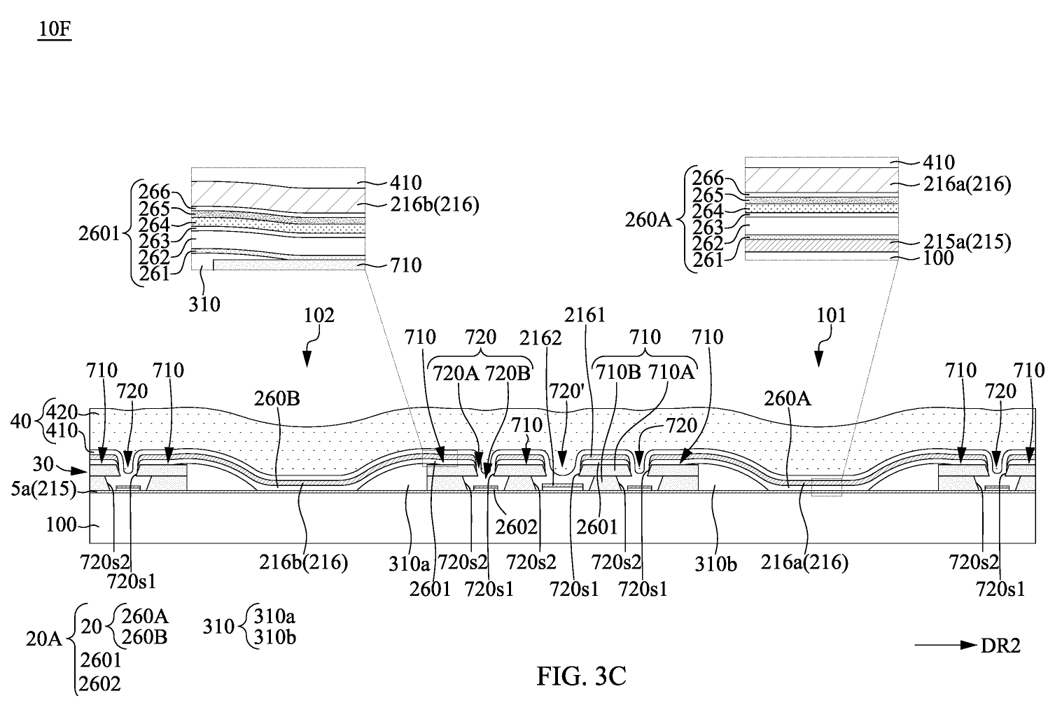

FIG. 3A is a cross sectional view exemplarily showing an organic light emitting device 10D. In some embodiments, FIG. 3A is a cross sectional view exemplarily showing the organic light emitting device 10 of FIG. 1. In some embodiments, FIG. 3A is a cross sectional view exemplarily taken along line A-A’ in FIG. 1. In some embodiments, FIG. 3A is a cross sectional view exemplarily taken along line A-A’ in FIG. 1 and illustrating only a light emitting region. FIG. 3A has a structure similar to the structure of FIG. 2A, with a difference described as follows.

In some embodiments, the spacer structure 30 (or the pixel defined layer) is disposed on the substrate 100 between the electrode 216a and the electrode 216b, and the spacer structure 30 partially extends onto the blocking structure 70. In some embodiments, the blocking structure has a cross sectional width tapering toward the substrate 100. In some embodiments, the blocking structure 70 contacts the substrate 100. In some embodiments, the trench 720 exposes a top surface of the electrode 215a.

In some embodiments, each protrusion 310 of the spacer structure 30 comprise a protrusion 310a and a protrusion 310b that are separated from each other. In some embodiments, the protrusion 310a and the protrusion 310b partially extends onto different blocking strips 710. In some embodiments, the protrusion 310a and the protrusion 310b are separated from each other by the blocking structure 70. In some embodiments, the spacer structure 30 may comprise a light sensitive material. In some embodiments, the blocking structure 70 may comprise a light sensitive material. In some embodiments, the blocking structure 70 may comprise an inorganic oxide such as silicon oxide, silicon nitride, or silicon oxynitride.

According to some embodiments of the disclosure, the blocking structure 70 and the spacer structure 30 collectively have a reduced height, and the capping layer 410 and the encapsulation layer 420 can be formed on a relatively planar surface. Therefore, stress concentration points in the capping layer 410 become fewer, thereby the cap layer 410 is less likely to be damaged, and the overall size of the organic light emitting device 10D can be further reduced.

FIG. 3B is a cross sectional view exemplarily showing an organic light emitting device 10E. In some embodiments, FIG. 3B is a cross sectional view exemplarily showing the organic light emitting device of FIG. 1. In some embodiments, FIG. 3B is a cross sectional view exemplarily taken along line A-A’ in FIG. 1. In some embodiments, FIG. 3B is a cross sectional view exemplarily taken along line A-A’ in FIG. 1 and illustrating only a light emitting region. FIG. 3B has a structure similar to the structure of FIG. 2A, with a difference described as follows.

In some embodiments, the blocking structure 70 has concave curved sidewalls 720s. In some embodiments, the blocking strips 710 have the concave curved sidewalls 720s.

FIG. 3C is a cross sectional view exemplarily showing an organic light emitting device 10F. In some embodiments, FIG. 3C is a cross sectional view exemplarily showing the organic light emitting device 10 of FIG. 1. In some embodiments, FIG. 3C is a cross sectional view exemplarily taken along line A-A’ in FIG. 1. In some embodiments, FIG. 3C is a cross sectional view exemplarily taken along line A-A’ in FIG. 1 and illustrating only a light emitting region. FIG. 3C has a structure similar to the structure of FIG. 2A, with a difference described as follows.

In some embodiments, a blocking strip 710 comprises an upper portion 710A and a lower portion 710B, and the upper portion 710A has a width greater than a width of the lower portion 710B. In some embodiments, both of the width of the upper portion 710A and the width of the lower portion 710B taper away from the substrate 100. In some embodiments, the upper portion 710A and the lower portion 710B comprise different materials. In some embodiments, the upper portion 710A and the lower portion 710B may comprise different inorganic oxide, for example, the upper portion 710A may comprise silicon oxide, and the lower portion 710B may comprise silicon nitride or silicon oxynitride. In some embodiments, the trench 720 has an upper trench region 720A and a lower trench region 720B, and the upper trench portion region 720A has a width less than a width of the lower portion region 720B. In some embodiments, the upper trench region 720A is defined by sidewalls 720s1 of the upper portion 710A. In some embodiments, the lower trench region 720A is defined by sidewalls 720s2 of the lower portion 710A. In some embodiments, the organic material layer 2601 extends onto the sidewalls of the upper portion 710A. In some embodiments, a width of an extension portion of the organic material layer 2601 on a sidewall of the upper portion 710A tapers toward the substrate 100. In some embodiments, the electrode material layer 2161 extends to above the sidewalls of the upper portion 710A. In some embodiments, a width of an extension portion of the electrode material layer 2161 on a sidewall of the upper portion 710A tapers toward the substrate 100.

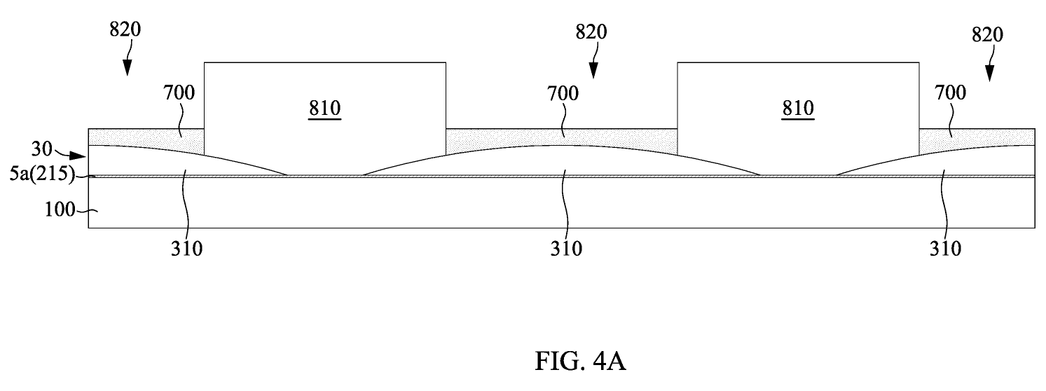

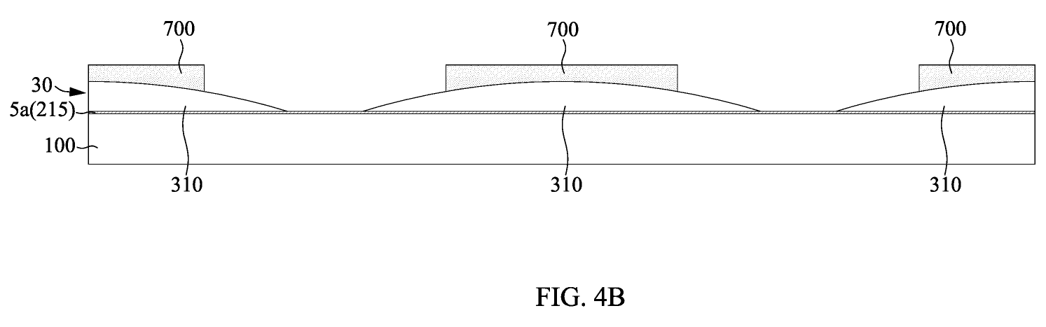

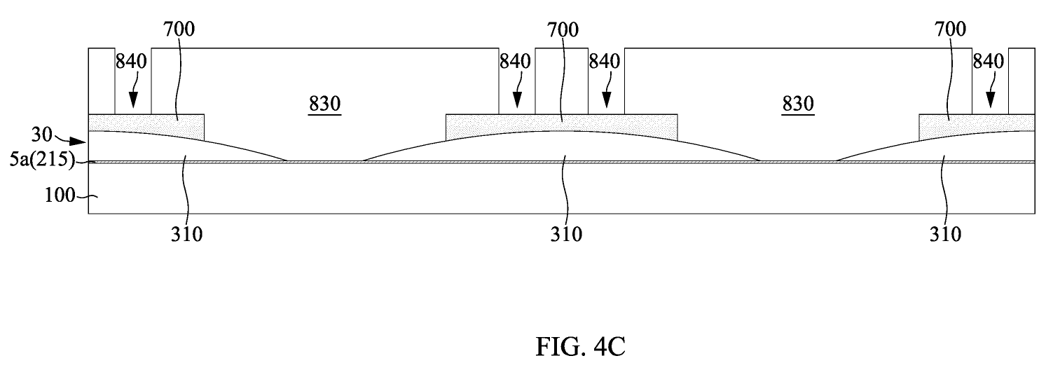

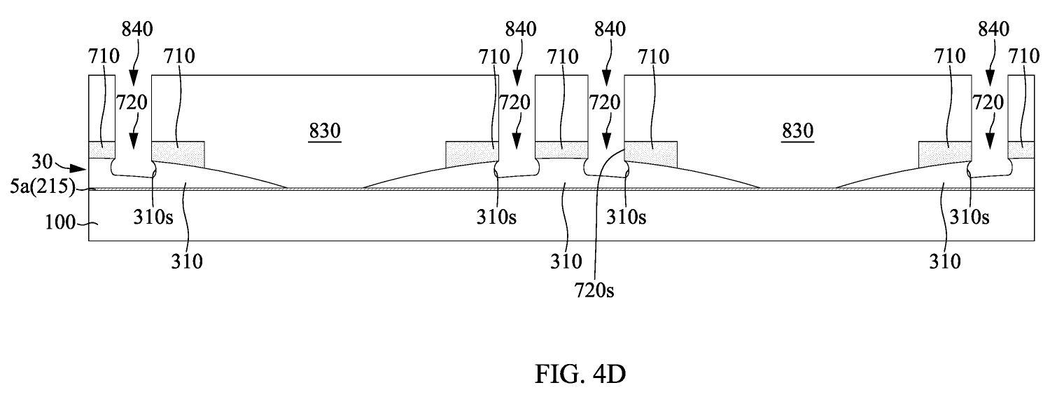

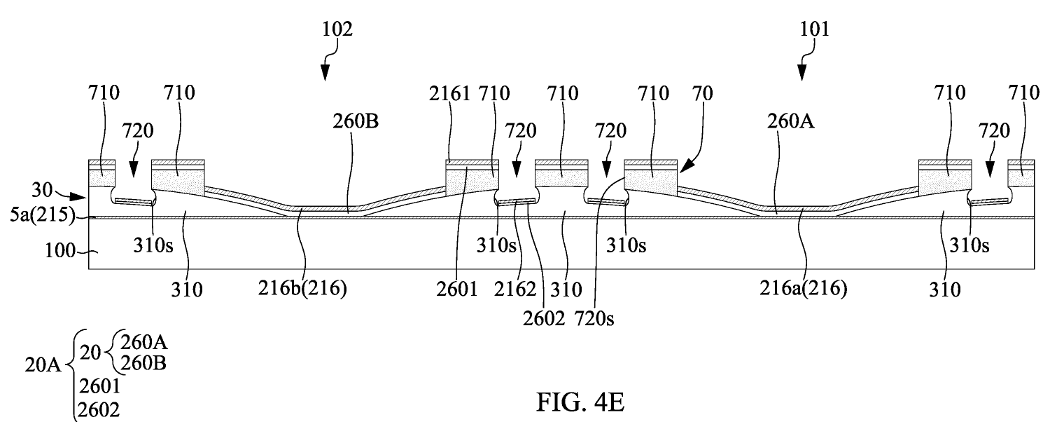

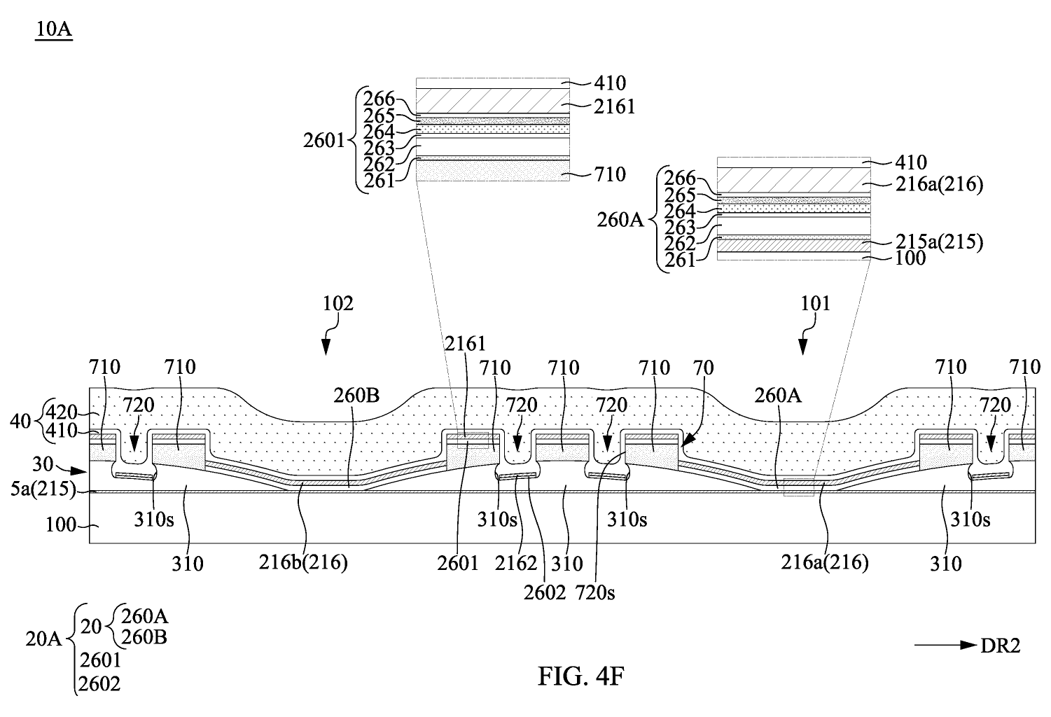

FIGS. 4A-4F show a method for manufacturing the organic light emitting device 10A according to some embodiments.

As shown in FIG. 4A, in some embodiments, a substrate 100 is provided, an electrode 215a is disposed on the substrate 100, and a plurality of protrusions 310 (or a spacer structure 30) are formed on the electrode 215a. In some embodiments, a plurality of electrodes 215 are disposed on the substrate 100 (as shown in FIG. 1), and the spacer structure 30 is formed on the plurality of electrodes 215. The plurality of electrodes 215 may be manufactured by photolithography and etching processes. Then, in some embodiments, a light sensitive layer 810 is disposed on the spacer structure 30 and the electrode 215a. In some embodiments, the light sensitive layer 810 is formed by coating. Then, in some embodiments, the light sensitive layer 810 is patterned by a lithography process, such that a portion of a protrusion 310 is exposed through a recess 820. Then, in some embodiments, a blocking material layer 700 is formed in the recess 820. In some embodiments, the blocking material layer 700 is formed by coating.

As shown in FIG. 4B, in some embodiments, the light sensitive layer 810 is removed. In some embodiments, the light sensitive layer 810 is removed by a wet etching process.

As shown in FIG. 4C, in some embodiments, a light sensitive layer 830 is disposed on the spacer structure 30 (or the pixel defined layer), the electrode 215a, and the blocking material layer 700. In some embodiments, the light sensitive layer 830 is formed by coating. Then, in some embodiments, the light sensitive layer 830 is patterned by a lithography process, such that a portion of the blocking material layer 700 is exposed through a recess 840.

As shown in FIG. 4D, in some embodiments, the portion of the blocking material layer 700 exposed through the recess 840 and a portion of the protrusion 310 are removed, so as to form a blocking structure 70 having blocking strips 710 and a trench 720. In some embodiments, the portion of the blocking material layer 700 and the portion of the protrusion 310 are removed by a descum process or a dry etching process. In some embodiments, the trench 720 is formed in the blocking structure 70 and further extended into the spacer structure 30 (or the pixel defined layer) by an etching step.

As shown in FIG. 4E, in some embodiments, the light sensitive layer 830 is removed. In some embodiments, the light sensitive layer 830 is removed by a wet etching process. Then, in some embodiments, an organic light emitting layer structure 20A and an electrode material layer are formed on the spacer structure 30, the electrode 215a, and the blocking structure 70.

In some embodiments, the electrode material layer is formed above the blocking structure 70 and the substrate 100, such that the electrode material layer is cut off by the blocking structure 70 to form an electrode 216a and an electrode 216b that are separated from each other. In some embodiments, a whole electrode material layer is formed on the spacer structure 30, the electrode 215a, and the blocking structure 70 by evaporation, such that the whole electrode material layer is cut off by the blocking strips 710 and the trench 720 to form the electrode 216a and the electrode 216b, which are separated from each other, an electrode material layer 2161 remaining on the blocking strips 710, and an electrode material layer 2162 remaining in the trench 720. In some embodiments, since the blocking strips 710 limit the amount of evaporation material entering the trench 720, the amount of electrode material entering the trench 720 is relatively reduced, and thus a thickness of the electrode material layer 2161 on the blocking strips 710 is greater than s thickness of the electrode material layer 2162 remaining in the trench 720.

In some embodiments, an organic light emitting material layer is formed above the blocking structure 70 and the substrate 100, such that the organic light emitting material layer is cut off by the blocking structure 70 to form an organic light emitting layer 260A and an organic light emitting layer 260B that are separated from each other. In some embodiments, a whole organic light emitting layer is formed on the spacer structure 30, the electrode 215a, and the blocking structure 70 by evaporation, such that the whole electrode material layer is cut off by the blocking strips 710 and the trench 720 to form the organic light emitting layer 260A and the organic light emitting layer 260B, which are separated from each other, an organic material layer 2601 remaining on the blocking strips 710, and an organic material layer 2602 remaining in the trench 720. Thus, organic light emitting units 101 and 102 are formed. In some embodiments, since the blocking strips 710 limit the amount of evaporation material entering the trench 720, the amount of organic light emitting material entering the trench 720 is relatively reduced, and thus a thickness of the organic material layer 2601 on the blocking strips 710 is greater than s thickness of the organic material layer 2602 remaining in the trench 720.

In some embodiments, a hole injection layer (HIL) 261 is disposed on surfaces of the spacer structure 30, the electrode 215a, and the blocking structure 70, a hole transport layer (HTL) 262 is disposed on the hole injection layer 261, an electron blocking layer (EBL) 263 is disposed on the hole transport layer 262, an organic emission layer (EM) 264 is disposed on the electron blocking layer 263, and then an electron transport layer (ETL) 265 is disposed on the organic emission layer 264, and an electron injection layer (EIL) 266 is disposed on the electron transport layer 265. In some embodiments, the hole injection layer 261, the hole transport layer 262, the electron blocking layer 263, the organic emission layer 264, the electron transport layer 265, and the electron injection layer 266 are formed by evaporation.

As shown in FIG. 4F, in some embodiments, a capping layer 410 is disposed on the electrode 216a and the electrode 216b. In some embodiments, the capping layer 410 is formed by evaporation. Then, in some embodiments, an encapsulation layer 420 is disposed on the capping layer 410. In some embodiments, the capping layer 410 is formed by evaporation. Thus, the organic light emitting device 10A as shown in FIG. 2A is formed.

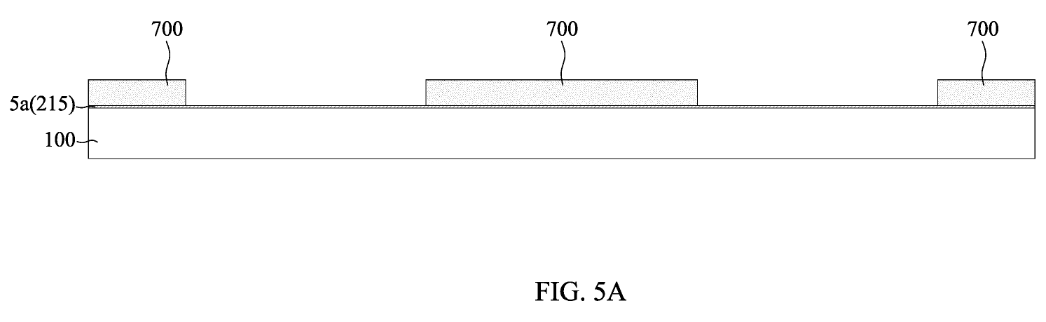

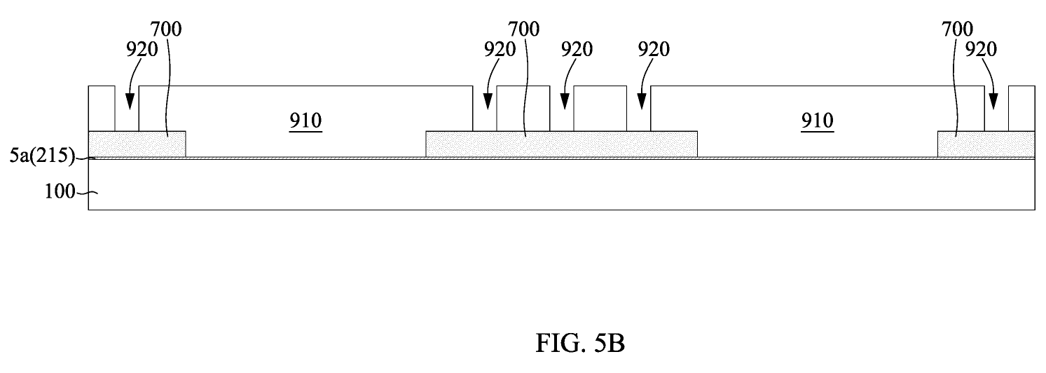

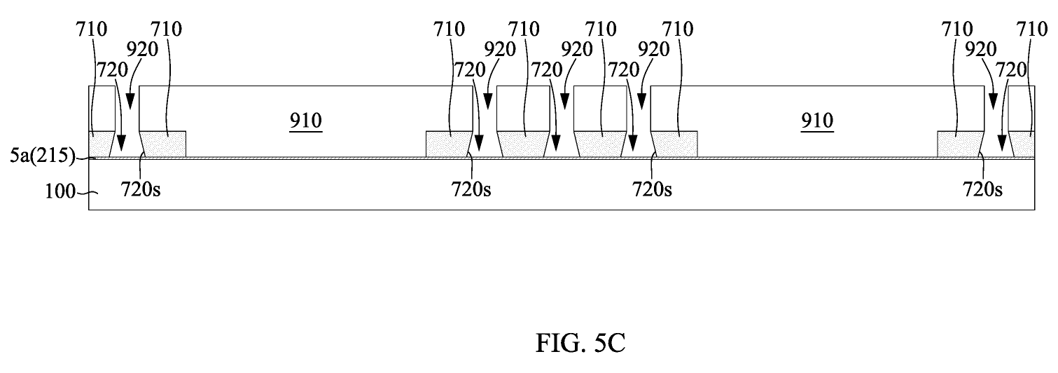

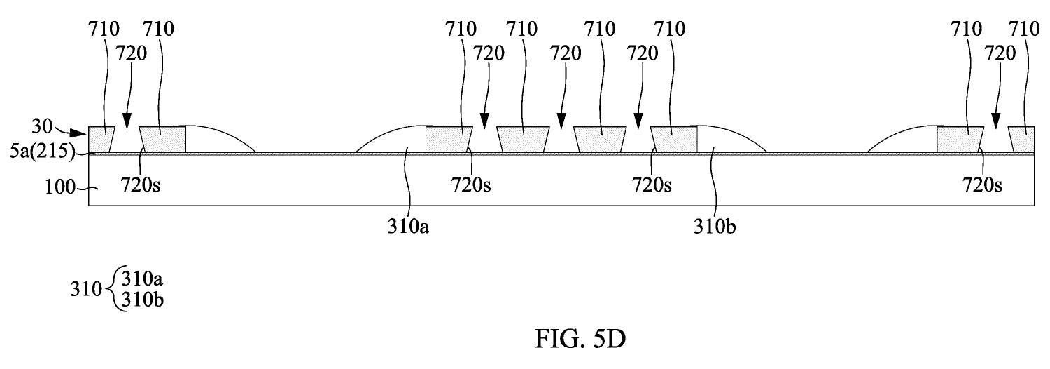

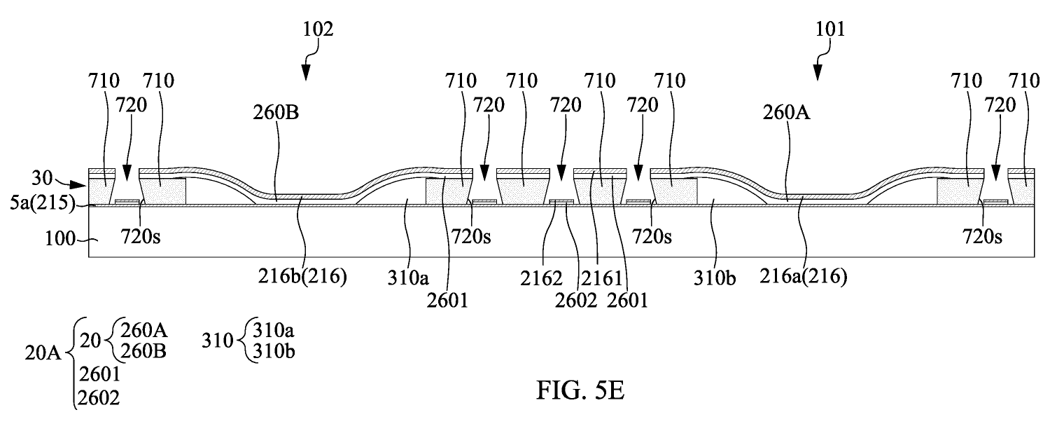

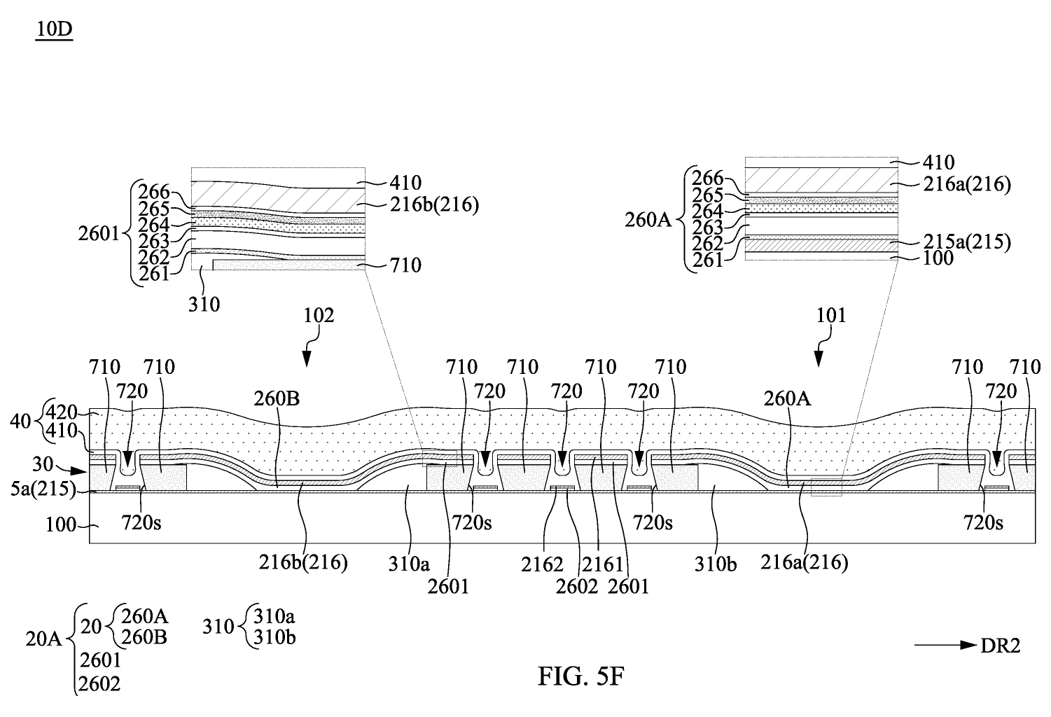

FIGS. 5A-5F show a method for manufacturing the organic light emitting device 10D according to some embodiments.

As shown in FIG. 5A, in some embodiments, a substrate 100 is provided, an electrode 215a is disposed on the substrate 100, and a blocking material layer 700 is formed on the electrode 215a. In some embodiments, a plurality of electrodes 215 are disposed on the substrate 100 (as shown in FIG. 1), and the blocking material layer 700 is formed on the plurality of electrodes 215. The plurality of electrodes 215 may be manufactured by photolithography and etching processes. In some embodiments, the blocking material layer 700 is formed by coating as well as photolithography and etching processes.

As shown in FIG. 5B, in some embodiments, a light sensitive layer 910 is disposed on the blocking material layer 700 and the electrode 215a. In some embodiments, the light sensitive layer 910 is formed by coating.

Then, in some embodiments, the light sensitive layer 910 is patterned by a lithography process, such that a portion of the blocking material layer 700 is exposed through a recess 920.

As shown in FIG. 5C, in some embodiments, the portion of the blocking material layer 700 exposed through the recess 920 is removed, so as to form a blocking structure 70 having blocking strips 710 and a trench 720. In some embodiments, the trench 720 is formed in the blocking structure 70 and a top surface of the electrode 215a is exposed by an etching step. In some embodiments, the portion of the blocking material layer 700 is removed by a descum process, a dry etching process, or a wet etching process.

As shown in FIG. 5D, in some embodiments, the light sensitive layer 910 is removed. In some embodiments, the light sensitive layer 910 is removed by a wet etching process.

As shown in FIG. 5E, in some embodiments, an organic light emitting layer structure 20A is formed on the spacer structure 30, the electrode 215a, and the blocking structure 70, and an electrode material layer is formed above the blocking structure 70, the spacer structure 30, and the substrate 100.

In some embodiments, the electrode material layer is formed above the blocking structure 70 and the substrate 100, such that the electrode material layer is cut off by the blocking structure 70 to form an electrode 216a and an electrode 216b that are separated from each other. In some embodiments, a whole electrode material layer is formed on the spacer structure 30, the electrode 215a, and the blocking structure 70 by evaporation, such that the whole electrode material layer is cut off by the blocking strips 710 and the trench 720 to form the electrode 216a and the electrode 216b, which are separated from each other, an electrode material layer 2161 remaining on the blocking strips 710, and an electrode material layer 2162 remaining in the trench 720.

In some embodiments, an organic light emitting material layer is formed above the blocking structure 70 and the substrate 100, such that the organic light emitting material layer is cut off by the blocking structure 70 to form an organic light emitting layer 260A and an organic light emitting layer 260B that are separated from each other. In some embodiments, a whole organic light emitting layer is formed on the spacer structure 30, the electrode 215a, and the blocking structure 70 by evaporation, such that the whole electrode material layer is cut off by the blocking strips 710 and the trench 720 to form the organic light emitting layer 260A and the organic light emitting layer 260B, which are separated from each other, an organic material layer 2601 remaining on the blocking strips 710, and an organic material layer 2602 remaining in the trench 720. Thus, organic light emitting units 101 and 102 are formed.

In some embodiments, a hole injection layer (HIL) 261 is disposed on surfaces of the spacer structure 30, the electrode 215a, and the blocking structure 70, a hole transport layer (HTL) 262 is disposed on the hole injection layer 261, an electron blocking layer (EBL) 263 is disposed on the hole transport layer 262, an organic emission layer (EM) 264 is disposed on the electron blocking layer 263, and then an electron transport layer (ETL) 265 is disposed on the organic emission layer 264, and an electron injection layer (EIL) 266 is disposed on the electron transport layer 265. In some embodiments, the hole injection layer 261, the hole transport layer 262, the electron blocking layer 263, the organic emission layer 264, the electron transport layer 265, and the electron injection layer 266 are formed by evaporation.

As shown in FIG. 5F, in some embodiments, a capping layer 410 is disposed on the electrode 216a and the electrode 216b. In some embodiments, the capping layer 410 is formed by evaporation. Then, in some embodiments, an encapsulation layer 420 is disposed on the capping layer 410. In some embodiments, the capping layer 410 is formed by evaporation. Thus, the organic light emitting device 10D as shown in FIG. 3A is formed.

The aforementioned content generally outlines the features of some implementations, allowing one skilled in the art to better understand various aspects of the disclosure. One skilled in the art should understand that hid disclosure can be easily used as a foundation to design or modify other processes and structures to achieve the same objectives and/or attain the same advantages as the embodiments described in the present application. One skilled in the art should also understand that such equivalent structures do not depart from the spirit and the scope of the disclosed content, and various changes, substitutions, and modifications can be made without departing from the spirit and the scope of the disclosure.

What is claimed is:

1. An organic light emitting device, comprising:
a substrate;
a first bottom electrode disposed on the substrate;
an organic light emitting layer structure disposed on the first bottom electrode;
a first top electrode and a second top electrode disposed on the organic light emitting layer structure; and
a blocking structure disposed on the substrate, wherein the blocking structure has a trench, and wherein the first top electrode and the second top electrode are separated from each other by the blocking structure.

2. The organic light emitting device according to claim 1, wherein the blocking structure comprises a plurality of blocking strips separated from each other by the trench.

3. The organic light emitting device according to claim 2, wherein the organic light emitting layer structure comprises:
a first organic light emitting layer disposed between the first bottom electrode and the first top electrode;
a second organic light emitting layer disposed between the first bottom electrode and the second top electrode, wherein the first organic light emitting layer and the second organic light emitting layer are separated from each other by the trench.

4. The organic light emitting device according to claim 2, wherein the first top electrode and the second top electrode have an extension direction substantially parallel to an extension direction of the trench.

5. The organic light emitting device according to claim 2, wherein the organic light emitting layer structure comprises:
a first organic light emitting layer and a second organic light emitting layer, wherein the first top electrode and the second top electrode are disposed on the first organic light emitting layer and the second organic light emitting layer, respectively;
a plurality of first organic material layers disposed on the blocking strips.

6. The organic light emitting device according to claim 5, wherein the organic light emitting layer structure comprises a second organic material layer disposed in the trench.

7. The organic light emitting device according to claim 1, wherein the trench has an extension direction substantially perpendicular to an extension direction of the first bottom electrode.

8. The organic light emitting device according to claim 1, further comprising:
a pixel defined layer disposed on the substrate between the first top electrode and the second top electrode, wherein the blocking structure is disposed on the pixel defined layer.

9. The organic light emitting device according to claim 1, further comprising:
a pixel defined layer disposed on the substrate between the first top electrode and the second top electrode, wherein the trench of the blocking structure is recessed toward an inside of the pixel defined layer.

10. The organic light emitting device according to claim 1, further comprising:
a pixel defined layer disposed on the substrate between the first top electrode and the second top electrode, wherein the pixel defined layer partially extends onto the blocking structure.

11. The organic light emitting device according to claim 1, wherein the blocking structure has a cross sectional width tapering toward the substrate.

12. The organic light emitting device according to claim 1, wherein the trench exposes a top surface of the first bottom electrode.

13. The organic light emitting device according to claim 1, comprising:
a plurality of the trench, wherein at least two of the trenches have different widths.

14. A method for manufacturing an organic light emitting device, comprising:
providing a substrate;
disposing a first bottom electrode on the substrate;
forming a blocking structure on the substrate;
forming a trench in the blocking structure;
forming an organic light emitting layer structure on the first bottom electrode and the blocking structure; and
forming a top electrode material layer over the blocking structure and the substrate, such that the top electrode material layer is cut off by the blocking structure to form a first top electrode and a second top electrode that are separated from each other.

15. The method according to claim 14, further comprising:
forming a pixel defined layer on the substrate and partially covering the first bottom electrode; and
forming the blocking structure on the pixel defined layer, wherein the top electrode material layer is cut off by a height difference between the blocking structure and the pixel defined layer.

16. The method according to claim 15, further comprising:
forming the trench in the blocking structure and further extending the trench into the pixel defined layer by an etching step.

17. The method according to claim 14, further comprising:
forming a pixel defined layer on the substrate and partially covering the first bottom electrode and the blocking structure, wherein the top electrode material layer is cut off by the trench.

18. The method according to claim 17, wherein forming the pixel defined layer is carried out after forming the trench.
